(19) United States
(12) Patent Application Publication
(10) Pub. No.: US 2022/0344477 A1
(43) Pub. Date: Oct. 27, 2022

(54) SEMICONDUCTOR DEVICE

(71) Applicant: FLOSFIA INC., Kyoto (JP)

(72) Inventors: Isao TAKAHASHI, Kyoto (JP); Kazuyoshi NORIMATSU, Kyoto (JP); Takashi SHINOHE, Kyoto (JP)

(21) Appl. No.: 17/860,670

(22) Filed: Jul. 8, 2022

Related U.S. Application Data
(63) Continuation-in-part of application No. PCT/JP2021/000574, filed on Jan. 8, 2021.

(30) Foreign Application Priority Data
Jan. 10, 2020 (JP) 2020-003248

(51) Int. Cl. H01L 29/24; H01L 29/10; H01L 23/46; H01L 29/04

(52) U.S. Cl. CPC H01L 29/24; H01L 29/1033; H01L 23/46; H01L 29/045; H01L 29/66568

(57) ABSTRACT

Provided is a semiconductor device including; at least a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of a c-axis in the semiconductor layer being the first direction.

### CROSS REFERENCE TO RELATED APPLICATION

This application is a continuation-in-part application of International Patent Application No. PCT/JP2021/000574 (Filed on Jan. 8, 2021), which claims the benefit of priority from Japanese Patent Application No. 2020-003248 (filed on Jan. 10, 2020).

The entire contents of the above applications, which the present application is based on, are incorporated herein by reference.

### 1. FIELD OF THE INVENTION

The disclosure relates to a semiconductor device useful, for example, for power devices.

### 2. DESCRIPTION OF THE RELATED ART

A conventional problem occurring during crystal growth on a heterogeneous substrate is cracks or crystal defect. In response to this problem, consideration has been given to providing conformity between the substrate and the grating constant or thermal expansion coefficient of a film, for example. In response to the occurrence of unconformity therebetween, consideration has also been given to employing a deposition method such as ELO.

According to a known method, a buffer layer is formed on a heterogeneous substrate and crystal growth of a zinc oxide-based semiconductor layer is caused on the buffer layer. Forming a nanodot mask on the heterogeneous substrate and then forming a single-crystal semiconductor material layer is known. There is a known method by which crystal growth of GaN is caused on sapphire through nano-columns of GaN. According to a known method, defect such as pits is reduced by causing crystal growth of GaN on Si (111) using periodic SiN interlayers.

However, all these techniques find difficulty in obtaining a high-quality epitaxial film for reason of an unsatisfactory deposition speed, the occurrence of a crack, dislocation, distortion, etc. at the substrate, or the occurrence of dislocation or a crack at an epitaxial film. This also causes a hindrance to increasing the diameter of the substrate or increasing the thickness of the epitaxial film.

Attention has been focused on a semiconductor device using gallium oxide (Ga₂O₃) having a wide band gap functioning as a next-generation switching element capable of achieving a high withstand voltage, low loss, and high resistance to heat. Application to a power semiconductor device such as an inverter is expected. Furthermore, the wide band gap is also expected to provide applied use as a light emitting and receiving device such as an LED or a sensor. This gallium oxide becomes controllable in band gap by using indium or aluminum alone, or a mixed crystal of indium and aluminum and forms an extremely attractive family of materials as InAlGaO-based semiconductors. Here, the InAlGaO-based semiconductors indicate In_{X}Al_{Y}Ga_{Z}O₃ (0≤X≤2, 0≤Y≤2, 0≤Z≤2, X+Y+Z=1.5 to 2.5) and may be regarded as a family of materials including gallium oxide.

However, as gallium oxide has a β-Gallia structure in the most stable phase, depositing a crystal film having a corundum structure is difficult unless a particular deposition method is used. Hence, a large number of problems are still left in terms of crystal quality, etc.

### SUMMARY OF THE INVENTION

According to an example of the present disclosure, there is provided a semiconductor device including; at least a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of a c-axis in the semiconductor layer being the first direction.

Thus, a semiconductor device of the disclosure is excellent in semiconductor characteristics, particularly in electrical characteristics.

### BRIEF DESCRIPTION OF THE DRAWINGS

FIG. 1 is a schematic configuration view of a deposition apparatus preferably used in the disclosure.

FIG. 2 is a schematic configuration view of a deposition apparatus (mist CVD) preferably used in the disclosure according to a different embodiment from FIG. 1.

FIG. 3 is a view schematically illustrating a preferred example of a power source system.

FIG. 4 is a view schematically illustrating a preferred example of a system device.

FIG. 5 is a view schematically illustrating a preferred example of a power source circuit diagram of a power source device.

FIG. 6 is a view schematically illustrating an example of a metal oxide semiconductor field-effect transistor (MOSFET) according to an embodiment of a semiconductor device according to the disclosure.

FIG. 7 illustrates a part of a schematic upper view according to an embodiment of the semiconductor device according to the disclosure.

FIG. 8 is a schematic partial sectional view according to an embodiment of the semiconductor device according to the disclosure illustrating an example of a section along A-A in FIG. 7, for example.

FIG. 9 is a partial sectional view illustrating a specific example according to an embodiment of the semiconductor device according to the disclosure and illustrating an example of the section along A-A in FIG. 7, for example.

FIG. 10 is a view schematically illustrating a preferred example of a power card.

FIG. 11 is a view illustrating result of a test example 1.

FIG. 12 is a view illustrating result of a test example 2.

FIG. 13 is a view illustrating result of a test example 3.

### DETAILED DESCRIPTION

The inventors of the present disclosure found out that electrical characteristics of the semiconductor device including a semiconductor layer containing gallium oxide with a corundum structure have anisotropy in relation to a direction of current flows, not a principal plane of the semiconductor layer. The inventors of the present disclosure have successfully created a semiconductor device including; at least a semiconductor layer; and a gate electrode that is arranged directly or via another layer on the semiconductor layer, the semiconductor device being configured in such a manner as to cause a current to flow in the semiconductor layer at least in a first direction that is along with an interface between the semiconductor layer and the gate electrode, the semiconductor layer having a corundum structure, a direction of a c-axis in the semiconductor layer being the first direction, and found out that the semiconductor device may solve the above-mentioned conventional problems.

Embodiments of the present disclosure will be described below with reference to the accompanying drawings. In the following description, the same parts and components are designated by the same reference numerals. The present embodiment includes, for example, the following disclosures.

### [Structure 1]

A semiconductor device including; at least a semiconductor layer; and a gate electrode that is arranged directly or via another layer on the semiconductor layer, the semiconductor device being configured in such a manner as to cause a current to flow at least in the semiconductor layer in a first direction that is along with an interface between the semiconductor layer and the gate electrode, the semiconductor layer having a corundum structure, a direction of a c-axis in the semiconductor layer being the first direction.

### [Structure 2]

The semiconductor device according to [Structure 1], wherein the first direction is a direction along with an upper surface of the semiconductor layer.

### [Structure 3]

The semiconductor device according to [Structure 1], wherein the semiconductor layer contains a metal oxide including at least one metal selected from gallium, indium, rhodium, and iridium.

### [Structure 4]

The semiconductor device according to [Structure 1], wherein the semiconductor layer contains a metal oxide including at least gallium as a major component.

### [Structure 5]

The semiconductor device according to any one of [Structure 1] to [Structure 4], wherein the semiconductor layer has a carrier concentration of equal to or less than 1×10¹⁹/cm³.

### [Structure 6]

The semiconductor device according to any one of [Structure 1] to [Structure 5], wherein the first surface is an m-plane.

### [Structure 7]

The semiconductor device according to any one of [Structure 1] to [Structure 6], wherein the semiconductor device is a power device.

### [Structure 8]

The semiconductor device according to [Structure 7], wherein the semiconductor device is a power module, an inverter, or a converter.

### [Structure 9]

The semiconductor device according to [Structure 7], wherein the semiconductor device is a power card.

### [Structure 10]

The semiconductor device according to [Structure 9], further including: a cooler and an insulating member, the cooler being provided on each of both sides of the semiconductor layer across at least the insulating member.

### [Structure 11]

The semiconductor device according to [Structure 10], wherein a heat dissipation layer is provided on each of the both sides of the semiconductor layer, and the cooler is provided external to the heat dissipation layer across at least the insulating member.

### [Structure 12]

A semiconductor system including a semiconductor device, the semiconductor device being the semiconductor device according to any one of [Structure 1] to [Structure 11].

A semiconductor device according to the disclosure includes at least a semiconductor layer, and a first electrode and a second electrode formed on the side of a first surface of the semiconductor layer. The semiconductor device is configured in such a manner as to cause a current to flow in the semiconductor layer in a first direction from the first electrode toward the second electrode. The semiconductor layer has a corundum structure and a direction of a c-axis in the semiconductor layer is the first direction.

According to an embodiment of the disclosure, the semiconductor layer contains a metal oxide including at least one metal selected from gallium, indium, rhodium, and iridium. According to an embodiment of the disclosure, the semiconductor layer contains a metal oxide including at least gallium as a major component. This achieves more excellent semiconductor characteristics in terms of increasing a withstand voltage, etc. The term “major component” herein means that the metal oxide has a content in terms of an atomic ratio of equal to or greater than 50% to all components in the semiconductor layer, means that the content is preferably equal to or greater than 70%, more preferably, equal to or greater than 90% in terms of an atomic ratio, and means that an atomic ratio may be 100% according to one embodiment. The metal oxide includes at least gallium and preferably, further includes indium, rhodium, or iridium. The metal oxide includes at least gallium and also preferably, further includes indium or/and aluminum. The metal oxide including at least gallium is more preferable as it achieves more excellent characteristics as a power device in terms of switching characteristics, for example. According to the disclosure, the first surface is preferably an m-plane as it achieves more excellent electrical characteristics.

Preferably, the semiconductor layer is a crystalline oxide semiconductor layer and contains a crystalline oxide semiconductor. The crystalline oxide semiconductor contains the metal oxide and preferably, includes at least gallium like in the above-described case, more preferably, includes gallium oxide and a mixed crystal of gallium oxide as a major component. According to the disclosure, while the crystalline oxide semiconductor is not particularly limited in terms of crystal structure, etc., the crystalline oxide semiconductor preferably contains a metal oxide having a corundum structure as a major component. While the metal oxide is not particularly limited, the metal oxide preferably includes one or two or more types of metals at least from the fourth period to the sixth period of the periodic table. The metal oxide more preferably includes at least gallium, indium, rhodium, or iridium, and most preferably, includes gallium. According to the disclosure, the metal oxide preferably includes gallium and indium or/and aluminum. Examples of the metal oxide including gallium include α-Ga₂O₃ or a mixed crystal of α-Ga₂O₃. The semiconductor layer including such a preferred metal oxide as a major component is provided with more excellent crystallinity and more excellent heat dissipation performance, and this might result in more excellent semiconductor characteristics. If the metal oxide is α-Ga₂O₃, for example, α-Ga₂O₃ may be contained in the semiconductor layer in such a manner that gallium in the semiconductor layer has an atomic ratio of equal to or greater than 50% to all the metal components in the semiconductor layer. According to the disclosure, the atomic ratio of gallium in the metal components in the semiconductor layer is preferably equal to or greater than 70%, more preferably, equal to or greater than 80% to all the metal components in the semiconductor layer. The semiconductor layer may be a single crystal or a poly crystal. The semiconductor layer is generally in a film shape. However, the semiconductor layer is not particularly limited but may be a plate shape or a sheet shape unless it interferes with the present disclosure.

The semiconductor layer may contain a dopant. The dopant is not particularly limited unless it interferes with the present disclosure. The dopant may be an n-type dopant or a p-type dopant. Examples of the n-type dopant include tin, germanium, silicon, titanium zirconium, vanadium, and niobium. A carrier concentration is properly settable, and more specifically, may be from about 1×10¹⁶ to about 1×10²²/cm³, for example. The carrier concentration may be set to a low concentration of equal to or less than about 1×10¹⁷/cm³, for example. In addition, as an example of an embodiment, a carrier concentration in the semiconductor layer may be set to a high concentration of equal to or greater than 1×10²⁰/cm³, for example. In an embodiment of the disclosure, however, reducing a carrier concentration in the semiconductor layer provides anisotropy more effectively to provide more favorable semiconductor characteristics. Thus, the carrier concentration is preferably set equal to or less than 1×10¹⁹/cm³, more preferably, equal to or less than 5×10¹⁸/cm³, most preferably, equal to or less than 1×10¹⁸/cm³.

The semiconductor layer may be obtained by a preferred deposition method described next, for example. For example, the semiconductor layer may be obtained by forming the semiconductor layer through epitaxial crystal growth by mist CVD method or mist epitaxy method conducted in such a manner as to cause a current to flow in the semiconductor layer in the first direction from the first electrode toward the second electrode while using a crystal substrate with a second side shorter than a first side and setting the c-axis direction to the first direction, and then by providing the semiconductor device.

### <Crystal Substrate>

The crystal structure is not particularly limited but may be a publicly-known substrate unless it interferes with the present disclosure. The crystal substrate may be an insulator substrate, a conductive substrate, or a semiconductor substrate. The crystal substrate may be a single-crystal substrate or a poly-crystal substrate. For example, the crystal substrate is a substrate containing a crystal substance having a corundum structure as a major component. The term “major component” herein means that the substrate contains the crystal substance in terms of a composition ratio of equal to or greater than 50%, preferably equal to or greater than 70%, more preferably, equal to or greater than 90%. Examples of the crystal structure having the corundum structure include a sapphire substrate, an α-type gallium oxide substrate, and an α-type mixed crystal substrate containing Ga₂O₃ and Al₂O₃ where Al₂O₃ is greater than 0 wt % and equal to or less than 60 wt %.

According to the disclosure, the crystal substrate is preferably a sapphire substrate. Examples of the sapphire substrate include a c-plane sapphire substrate, an m-plane sapphire substrate, an a-plane sapphire substrate, and an r-plane sapphire substrate. According to an embodiment of the disclosure, an m-plane sapphire substrate or an m-plane α-Ga₂O₃ substrate is preferably used. The sapphire substrate may have an off-angle. While the off-angle is not particularly limited and may be equal to or greater than 0.01°, for example, it is preferably equal to or greater than 0.2°, more preferably, from 0.2° to 12°. The sapphire substrate has a crystal growth plane that is preferably an a-plane, an m-plane, or an r-plane. The sapphire substrate is also preferably a c-plane sapphire substrate having an off-angle of equal to or greater than 0.2°.

While the thickness of the crystal substrate is not particularly limited, it is generally from 10 μm to 20 mm, more preferably, from 10 to 1000 μm.

According to the disclosure, control may be exerted on a direction of crystal growth, etc. in the semiconductor layer using an ELO mask in such a manner that the second side becomes shorter than the first side, a linear thermal expansion coefficient in a direction of a first crystal axis becomes lower than a linear thermal expansion coefficient in a direction of a second crystal axis, a direction of the first side becomes parallel or substantially parallel to the direction of the first crystal axis, and a direction of the second side becomes parallel or substantially parallel to the direction of the second crystal axis.

Examples of a preferred shape of the crystal substrate include a triangle, a quadrilateral (a rectangle or a trapezoid, for example), a polygon such as a pentagon or a hexagon, a U-shape, an inverted U-shape, an L-shape, and a channel-shape.

According to the disclosure, a different layer such as a buffer layer or a stress relief layer may be provided on the crystal substrate. For example, the buffer layer is a layer made of a metal oxide having the same crystal structure as the crystal structure of the crystal substrate or the semiconductor layer. For example, the stress relief layer is an ELO mask layer.

Means of the epitaxial crystal growth is not particularly limited but may be publicly-known means unless it interferes with the present disclosure. Examples of the means of the epitaxial crystal growth include CVD method, MOCVD method, MOVPE method, mist CVD method, mist epitaxy method, MBE method, HVPE method, pulse growth method, and ALD method. According to the disclosure, the means of the epitaxial crystal growth is preferably mist CVD method or mist epitaxy method.

The mist CVD method or the mist epitaxy method is conducted by atomizing a raw material solution containing metal (atomization step), causing droplets to float, carrying resultant atomized droplets to a vicinity of the crystal substrate with a carrier gas (carrying step), and then causing a thermal reaction of the atomized droplets (deposition step).

### (Raw Material Solution)

The raw material solution is not particularly limited as long as it contains metal as a deposition raw material and it is available for atomization. The raw material solution may contain an inorganic material or an organic material. The metal may be metal as a single element or a metal compound and is not particularly limited unless it interferes with the present disclosure. Examples of the metal include one or two or more types of metals selected from gallium (Ga), iridium (Ir), indium (In), rhodium (Rh), aluminum (Al), gold (Au), silver (Ag), platinum (Pt), copper (Cu), iron (Fe), manganese (Mg), nickel (Ni), palladium (Pd), cobalt (Co), ruthenium (Ru), chromium (Cr), molybdenum (Mo), tungsten (W), tantalum (Ta), zinc (Zn), lead (Pb), rhenium (Re), titanium (Ti), tin (Sn), magnesium (Mg), calcium (Ca), and zirconium (Zr). According to the disclosure, the metal preferably includes one or two or more types of metals at least from the fourth period to the sixth period of the periodic table, more preferably, includes at least gallium, indium, rhodium, or iridium. According to the disclosure, the metal also preferably includes gallium, and indium or/and aluminum. Using such a preferred metal makes it possible to deposit the semiconductor layer usable preferably in a semiconductor device, etc.

According to the disclosure, a solution containing the metal, in a form of complex or salt, dissolved or dispersed in an organic solvent or water may be used preferably as the raw material solution. Examples of the form of the complex include an acetylacetonate complex, a carbonyl complex, an ammine complex, and a hydride complex. Examples of the form of the salt include an organic metal salt (e.g., metal acetate, metal oxalate, metal citrate, etc.), metal sulfide, metal nitrate, phosphorylated metal, and metal halide (e.g., metal chloride, metal bromide, metal iodide, etc.).

A solvent of the raw material solution is not particularly limited unless it interferes with the present disclosure. The solvent may be an inorganic solvent such as water, an organic solvent such as alcohol, or a mixed solvent of the inorganic solvent and the organic solvent. According to the disclosure, the solvent preferably includes water.

Furthermore, the raw material solution may contain a mixed additive such as a hydrohalic acid or an oxidant. Examples of the hydrohalic acid include hydrobromic acid, hydrochloric acid, and hydroiodic acid. Examples of the oxidant include peroxide such as hydrogen peroxide (H₂O₂), sodium peroxide (Na₂O₂), barium peroxide (BaO₂), and benzoyl peroxide (C₆H₅CO)₂O₂, hypochlorous acid (HClO), perchloric acid, nitric acid, ozone water, and an organic peroxide such as peracetic acid and nitrobenzene.

The raw material solution may contain a dopant. The dopant is not particularly limited unless it interferes with the present disclosure. Examples of the dopant include n-type dopants. The n-type dopants may include tin, germanium, silicon, titanium, zirconium, vanadium and niobium. Also, examples of the dopant include p-type dopants. The dopant has a concentration that may, in general, be approximately in a range from 1×10¹⁶ to 1×10²²/cm³. The dopant concentration may be at a lower concentration of, for example, approximately equal to or less than 1×10¹⁷/cm³. In addition, according to the disclosure, the dopant may be contained at a high concentration of, for example, approximately equal to or greater than 1×10²⁰/cm³.

### (Atomization Step)

At the atomization step, the raw material solution containing the metal is adjusted, the raw material solution is atomized, droplets are caused to float, and then the atomized droplets are generated. While the ratio of the mixed metal is not particularly limited, it is preferably from 0.0001 mol/L to 20 mol/L to the raw material solution in its entirety. Means of the atomization is not particularly limited and may be publicly-known atomization means as long as it is available for atomization of the raw material solution. According to the disclosure, the atomization means preferably uses ultrasonic vibration. Mist used in the disclosure is to float in the air and is not to be blown like a spray, for example. More preferably, the mist has a zero initial velocity, is to float in the space, and is carriable as a gas. The droplet size of the mist is not particularly limited and may be a droplet of about several millimeters, but is preferably equal to or less than 50 μm, more preferably, from 1 to 10 μm.

### (Carrying Step)

At the carrying step, the atomized droplets are carried to the substrate by using the carrier gas. The type of the carrier gas is not particularly limited unless it interferes with the disclosure. Preferred examples of the carrier gas include oxygen, ozone, an inert gas (such as nitrogen or argon, for example), and a reduction gas (such as hydrogen gas or forming gas). Further, the carrier gas may contain one or two or more types of gas. Also, a diluted gas (e.g., 10-fold diluted gas) and the like changed in carrier gas concentration may be further used as a second carrier gas. A location for supplying the carrier gas is not limited to one but the carrier gas may be supplied from two or more locations. While the flow rate of the carrier gas is not particularly limited, it is preferably equal to or less than 1 LPM, more preferably, from 0.1 to 1 LPM.

### (Deposition Step)

At the deposition step, a reaction of the atomized droplets is caused to deposit a film on the crystal substrate. The reaction is not particularly limited as long as it is to form a film from the atomized droplets. According to the disclosure, a thermal reaction is preferred. The thermal reaction is simply required to be a reaction of the atomized droplets using heat. Conditions, etc. for the reaction are not particularly limited unless they interfere with the present disclosure. At this step, the thermal reaction is generally conducted at a temperature equal to or higher than an evaporation temperature of the solvent of the raw material solution. Preferably, this temperature does not exceed an excessively high temperature and more preferably, it is equal to or less than 650° C. The thermal reaction may be conducted in any atmosphere such as a vacuum atmosphere, a non-oxygen atmosphere, a reducing gas atmosphere, or an oxygen atmosphere, or may be conducted in any condition such as being under atmospheric pressure, under increased pressure, or under a reduced pressure unless they interfere with the present disclosure. According to the disclosure, the thermal reaction is preferably conducted under an atmospheric pressure in terms of facilitating calculation of an evaporation temperature, simplifying equipment, etc. Furthermore, a film thickness is settable through adjustment of a deposition time.

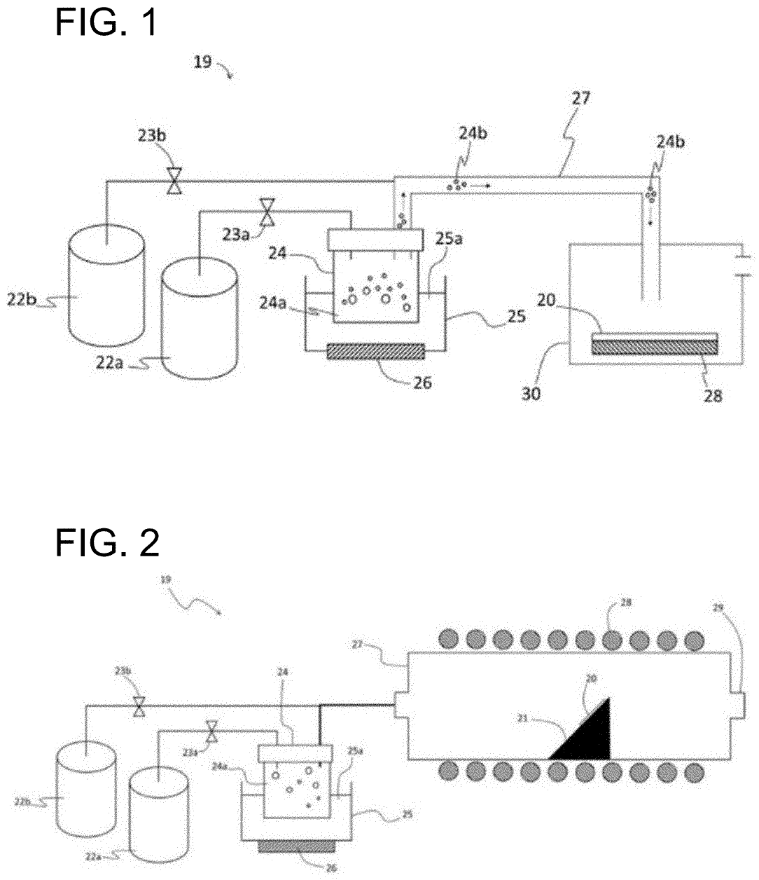

A deposition apparatus 19 preferably used in the disclosure will be described below by referring to the drawings. The deposition apparatus 19 in FIG. 1 includes: a carrier gas source 22a to supply a carrier gas; a flow control valve 23a for controlling the flow rate of the carrier gas supplied from the carrier gas source 22a; a carrier gas (diluted) source 22b to supply a carrier gas (diluted); a flow control valve 23b for controlling the flow rate of the carrier gas (diluted) supplied from the carrier gas (diluted) source 22b; a mist generator 24 containing a raw material solution 24a; a container 25 containing water 25a; an ultrasonic transducer 26 attached to the bottom surface of the container 25; a deposition chamber 30; a supply pipe 27 made of quartz forming connection from the mist generator 24 to the deposition chamber 30; and a hot plate (heater) 28 installed in the deposition chamber 30. A substrate 20 is placed on the hot plate 28.

As illustrated in FIG. 1, the raw material solution 24a is stored in the mist generator 24. Next, the substrate 20 is placed on the hot plate 28 and the hot plate 28 is actuated to increase a temperature in the deposition chamber 30. Next, the flow control valve 23 (23a, 23b) is opened to supply the carrier gas from the carrier gas source 22 (22a, 22b) into the deposition chamber 30. After an atmosphere in the deposition chamber 30 is sufficiently replaced with the carrier gas, the flow rate of the carrier gas and the flow rate of the carrier gas (diluted) are controlled. Next, the ultrasonic transducer 26 is vibrated and resultant vibration is propagated through the water 25a to the raw material solution 24a. By doing so, the raw material solution 24a is atomized to generate atomized droplets 24b. The atomized droplets 24b are introduced into the deposition chamber 30 using the carrier gas and carried to the substrate 20. Then, the atomized droplets 24b cause a thermal reaction in the deposition chamber 30 under atmospheric pressure to form a film (semiconductor layer) on the substrate 20.

A mist CVD apparatus 19 is preferably used as a deposition apparatus illustrated in FIG. 2. The mist CVD apparatus 19 in FIG. 2 includes: a susceptor 21 on which a substrate 20 is placed; carrier gas supply means 22a to supply a carrier gas; a flow control valve 23a for controlling the flow rate of the carrier gas supplied from the carrier gas supply means 22a; carrier gas (diluted) supply means 22b to supply a carrier gas (diluted); a flow control valve 23b for controlling the flow rate of the carrier gas supplied from the carrier gas (diluted) supply means 22b; a mist generator 24 containing a raw material solution 24a; a container 25 containing water 25a; an ultrasonic transducer 26 attached to the bottom surface of the container 25; a supply pipe 27 having an inner diameter of 40 mm made of quartz pipe; a heater 28 installed around the supply pipe 27; and an exhaust port 29 for ejection of mist, droplets, and exhaust gas after a thermal reaction. The susceptor 21 is made of quartz and has a surface for placement of the substrate 20 that is slanted off a horizontal plane. Using quartz both for forming the supply pipe 27 and the susceptor 21 as a deposition chamber reduces the occurrence of mixture of impurity derived from the apparatus into a film to be formed on the substrate 20. The mist CVD apparatus 19 may be handled in the same way as the deposition apparatus 19 described above.

Using the preferred deposition apparatuses described above makes it possible to form the semiconductor layer more easily on a crystal growth surface of the crystal substrate. The semiconductor layer is generally formed through epitaxial crystal growth.

The above-described semiconductor layer is useful for semiconductor devices, particularly useful for power devices. Examples of the semiconductor device formed by using the above-described semiconductor layer include a transistor such as an MIS transistor or an HEMT or a TFT, a Schottky barrier diode using a semiconductor-metal junction, a JBS, a PN or PIN diode using a combination with another P layer, and a light emitting and receiving element. According to the disclosure, the crystalline oxide semiconductor is grown to become a semiconductor layer and is removed from the crystal substrate, if needed. Then, this semiconductor layer becomes usable as a semiconductor layer (film) in a semiconductor device. The semiconductor layer is also usable by being placed on a substrate having higher thermal conductivity than the crystal substrate.

The semiconductor device is preferably used in a lateral element (lateral device) with an electrode formed on the side of one surface of a semiconductor layer. Preferred examples of this semiconductor device include a Schottky barrier diode (SBD), a junction barrier Schottky diode (JBS), a metal semiconductor field-effect transistor (MESFET), a high electron mobility transistor (HEMT), a metal oxide semiconductor field-effect transistor (MOSFET), a static induction transistor (SIT), a junction field-effect transistor (JFET), an insulated gate bipolar transistor (IGBT), and a light-emitting diode (LED).

The following describes preferred examples of the semiconductor device using the semiconductor layer of the disclosure as an n-type semiconductor layer (n⁺-type semiconductor layer or n⁻-type semiconductor layer, for example) by referring to the drawings. However, the disclosure is not limited to these examples.

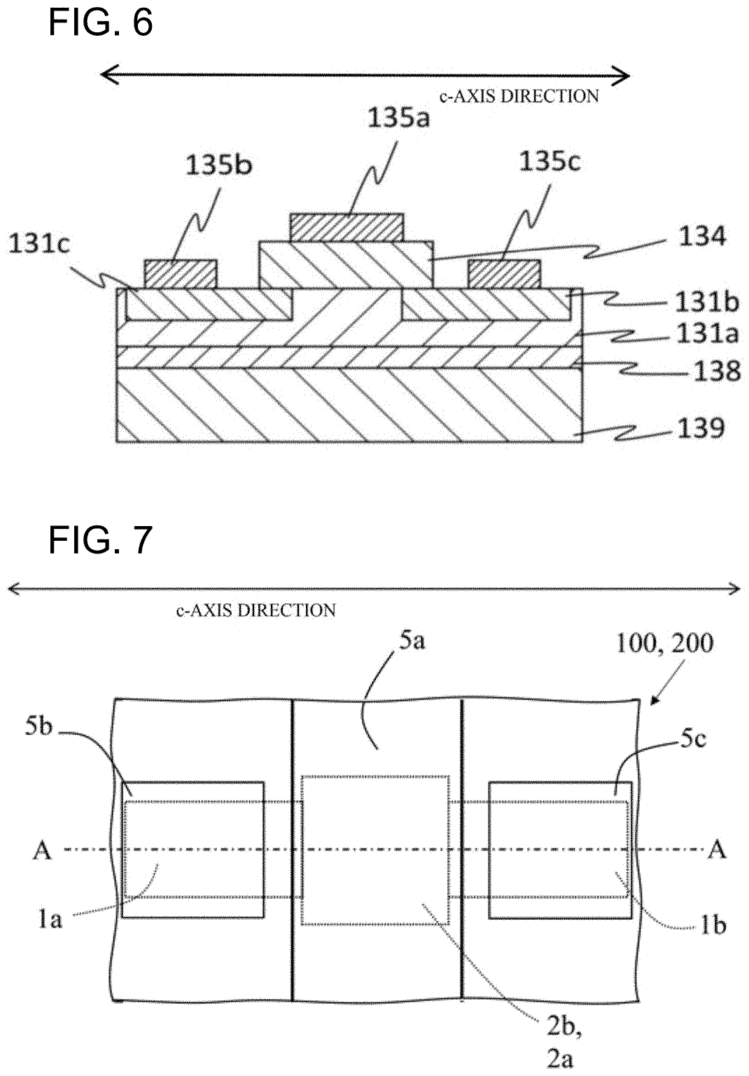

FIG. 6 illustrates an example of a lateral MOSFET. The semiconductor device according to an embodiment of the disclosure includes at least one semiconductor layer (131a, for example), and at least a first electrode (135b, for example) and a second electrode (135c, for example) both arranged on the side of a first surface of the semiconductor layer. The semiconductor device is configured in such a manner that a current flows in the semiconductor layer in a first direction from the first electrode toward the second electrode. The semiconductor layer has a corundum structure and a direction of a c-axis in the semiconductor layer is the first direction. According to an embodiment of the disclosure, the first surface of the semiconductor layer is preferably an m-plane. This preferred embodiment achieves more favorable electrical characteristics of the semiconductor device. More specifically, the MOSFET in FIG. 6 includes an n⁻-type semiconductor layer 131a, a first n⁺-type semiconductor layer 131b, a second n⁺-type semiconductor layer 131c, a gate insulating film 134, a gate electrode 135a, a source electrode 135b, a drain electrode 135c, a buffer layer 138, and a semi-insulator layer 139. As illustrated in FIG. 6, for example, embedding the n⁺-type semiconductor layer in the n⁻-type semiconductor layer makes it possible to cause a current to flow more favorably than other types of lateral MOSFETs. Also, as apparent from FIG. 6, a current flows in the n⁻-type semiconductor layer 131a at least in the first direction that is along with an interface between the n⁻-type semiconductor layer 131a and the gate electrode 135a (the gate insulating film 134).

A material of the electrode may be a publicly-known electrode material. Examples of this electrode material include metals such as Al, Mo, Co, Zr, Sn, Nb, Fe, Cr, Ta, Ti, Au, Pt, V, Mn, Ni, Cu, Hf, W, Ir, Zn, In, Pd, Nd, and Ag, alloys of these metals, conductive films made of metal oxides such as tin oxide, zinc oxide, rhenium oxide, indium oxide, indium tin oxide (ITO), and indium zinc oxide (IZO), organic conductive compounds such as polyaniline, polythiophene, and polypyrrole, and mixtures and multilayer structures thereof.

The electrode may be formed by publicly-known means such as vacuum evaporation or sputtering, for example. More specifically, in forming the electrode using two types of metals including a first metal and a second metal from the above-listed metals, a layer made of the first metal and a layer made of the second metal are stacked. Then, patterning using photolithography is performed on the layer made of the first metal and the layer made of the second metal, thereby forming the electrode.

FIG. 7 illustrates a part of a schematic upper view for explaining a principal part according to an embodiment of the semiconductor device according to the disclosure. The number of electrodes of the semiconductor device, the shapes of the electrodes, and arrangement of the electrodes are selectable appropriately.

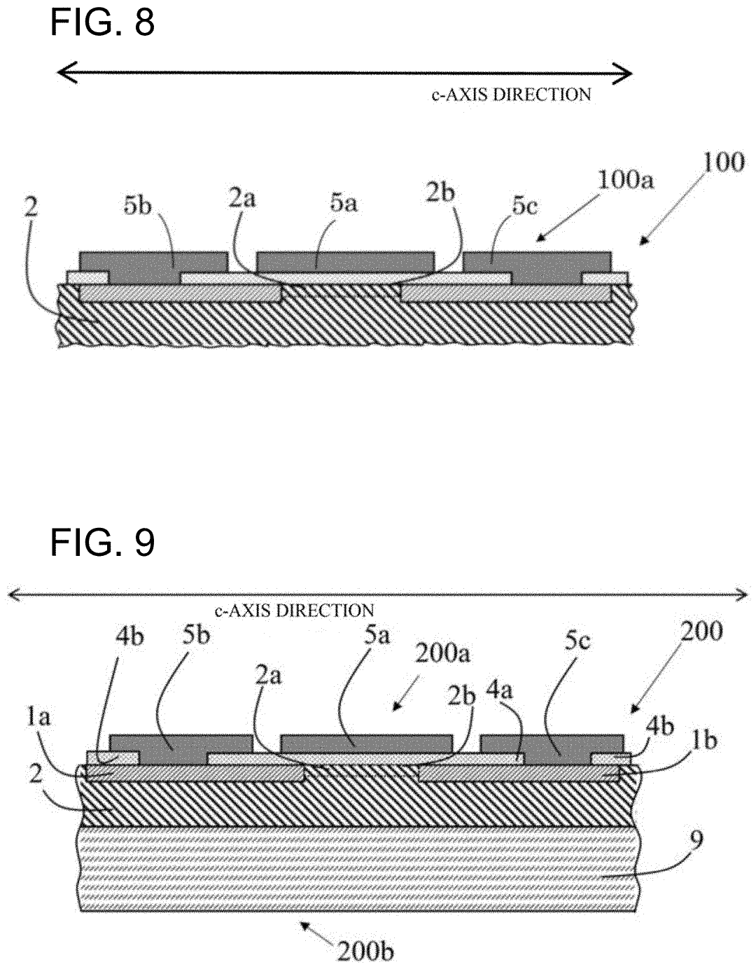

FIG. 8 is a partial sectional view for explaining a principal part according to an embodiment of the semiconductor device according to the disclosure and illustrates a section along A-A in FIG. 7, for example. A semiconductor device 100 according to an embodiment of the disclosure includes at least one semiconductor layer (2, for example), and at least a first electrode (5b, for example) and a second electrode (5c, for example) both arranged on the side of a first surface of the semiconductor layer 2. The semiconductor device is configured in such a manner that a current flows in the semiconductor layer in a first direction from the first electrode toward the second electrode. The semiconductor layer has a corundum structure and a direction of a c-axis in the semiconductor layer is the first direction. According to an embodiment of the disclosure, the first surface of the semiconductor layer is preferably an m-plane. This preferred embodiment achieves more favorable electrical characteristics of the semiconductor device. The semiconductor device 100 includes an oxide semiconductor film 2 containing crystal including at least gallium oxide. The oxide semiconductor film 2 includes an inversion channel region 2a. The crystal includes gallium oxide as a major component. The crystal may be a mixed crystal. The semiconductor device 100 includes an oxide film 2b at a position contacting the inversion channel region 2a. Also, as apparent from FIG. 8, a current flows in the semiconductor layer 2 at least in the first direction that is along with an interface between the semiconductor layer 2 and the third electrode 5a (the gate insulating film 4a).

FIG. 9 is a schematic sectional view for explaining a specific example according to an embodiment of the semiconductor device according to the disclosure and illustrates an example of a specific section along A-A in FIG. 7, for example. A semiconductor device 200 according to an embodiment of the disclosure includes at least one semiconductor layer (2, for example), and at least a first electrode (5b, for example) and a second electrode (5c, for example) both arranged on the side of a first surface of the semiconductor layer 2. The semiconductor device is configured in such a manner that a current flows in the semiconductor layer in a first direction from the first electrode toward the second electrode. The semiconductor layer has a corundum structure and a direction of a c-axis in the semiconductor layer is the first direction. According to an embodiment of the disclosure, the first surface of the semiconductor layer is preferably an m-plane. This preferred embodiment achieves more favorable electrical characteristics of the semiconductor device.

The semiconductor device 200 includes an oxide semiconductor film 2 containing crystal including at least gallium oxide. The oxide semiconductor film 2 includes an inversion channel region 2a. The crystal has a corundum structure. The semiconductor device 200 further includes a first semiconductor region 1a and a second semiconductor region 1b. As illustrated in FIG. 9, according to this embodiment, the inversion channel region 2a is located between the first semiconductor region 1a and the second semiconductor region 1b in a plan view. In response to application of a voltage to the semiconductor device 200, the inversion channel region of the oxide semiconductor film 2 is inverted to form electrical continuity between the first semiconductor region 1a and the second semiconductor region 1b. According to this embodiment, the first semiconductor region 1a and the second semiconductor region 1b are located in the oxide semiconductor film 2, and are arranged in the oxide semiconductor film 2 in such a manner that the upper surface of the first semiconductor region 1a, the upper surface of the second semiconductor region 1b, and the upper surface of the inversion channel region 2a become flush with each other. On a first surface side 200a of the semiconductor device 200, the first semiconductor region 1a, the oxide semiconductor film 2 including the inversion channel region 2a, and the second semiconductor region 1b form a planar surface, thereby facilitating design including arrangement of the electrodes and encouraging thickness reduction of the semiconductor device. As described below, a configuration where the oxide semiconductor film 2 includes an oxide film 2b provided in contact with the inversion channel region 2a is included in the configuration where the first semiconductor region 1a, the oxide semiconductor film 2 including the inversion channel region 2a, and the second semiconductor region 1b form a planar surface. The first semiconductor region 1a and the second semiconductor region 1b may be embedded in the oxide semiconductor film 2 or may be arranged in the oxide semiconductor film 2 through ion implantation. The oxide semiconductor film 2 according to this embodiment is a p-type semiconductor film, and the first semiconductor region 1a and the second semiconductor region 1b are n-type. The oxide semiconductor film 2 may contain a p-type dopant. The semiconductor device 200 may further include an oxide film 2b arranged on the inversion channel region 2a. According to an embodiment of the disclosure, the oxide film 2b preferably has a crystal structure belonging to a trigonal system to which a corundum structure belongs. The oxide film 2b includes at least one element in Group 15 of the periodic table and preferably includes phosphorus. According to another embodiment, the oxide film 2b may further include at least one element in Group 13 of the periodic table. The semiconductor device 200 includes a first electrode 5b electrically connected to the first semiconductor region 1a and a second electrode 5c electrically connected to the second semiconductor region 1b. The semiconductor device 200 further includes a third electrode 5a provided between the first electrode 5b and the second electrode 5c and separated from the inversion channel region 2a by an insulating film 4a. As illustrated in the drawing, the first electrode 5b, the second electrode 5c, and the third electrode 5a are arranged on the first surface side 200a of the semiconductor device 200. More specifically, the semiconductor device 200 includes the insulating film 4a arranged on the oxide film 2b on the inversion channel region 2a and the third electrode 5a is arranged on the insulating film 4a. In the semiconductor device 200, while the first electrode 5b and the first semiconductor region 1a are electrically connected to each other, an insulating film 4b located partially between the first electrode 5b and the first semiconductor region 1a may be provided. Moreover, while the second electrode 5c and the second semiconductor region 1b are electrically connected to each other, an insulating film 4b located partially between the second electrode 5c and the second semiconductor region 1b may also be provided. The semiconductor device 200 may further include another layer on a second surface side 200b of the semiconductor device 200, namely, on a lower surface side of the oxide semiconductor film 2. As illustrated in FIG. 9, the semiconductor device 200 may include a substrate 9. As illustrated in FIG. 7, the first semiconductor region 1a has a part overlapping the first electrode 5b and a part overlapping the third electrode 5a in a plan view. The second semiconductor region 1b has a part overlapping the second electrode 5c and a part overlapping the third electrode 5a in a plan view. According to this embodiment, in response to application of a voltage to the third electrode 5a that is positive relative to the first electrode 5b, the inversion channel region 2a of the oxide semiconductor film 2 is inverted from the p-type to the n-type to form an n-type channel layer. This forms electrical continuity between the first semiconductor region 1a and the second semiconductor region 1b to cause electrons to flow from a source electrode to a drain electrode. Additionally, setting a voltage at the third electrode 5a zero prevents formation of a channel layer in the inversion channel region 2a to make a turn-off state. According to this embodiment, the first electrode 5b may be a source electrode, the second electrode 5c may be a drain electrode, and the third electrode 5a may be a gate electrode. In this case, the insulating film 4a is a gate insulating film and the insulating film 4b is a field insulating film.

The oxide semiconductor film containing crystal including gallium oxide and/or the oxide semiconductor film containing crystal having a corundum structure may be obtained by deposition using an epitaxial crystal growth method. The epitaxial crystal growth method is not particularly limited but may be a publicly-known method unless it interferes with the present disclosure. Examples of the epitaxial crystal growth method include CVD method, MOCVD (metal organic chemical vapor) method, MOVPE (metal organic vapor-phase epitaxy) method, mist CVD method, mist epitaxy method, MBE (molecular beam epitaxy) method, HVPE (hydride vapor phase epitaxy) method, and pulse growth method. According to an embodiment of the disclosure, if the oxide semiconductor film is to be formed by the epitaxial crystal growth, mist CVD method or mist epitaxy method is preferably used.

Examples of a material of the first electrode 5b and that of the second electrode 5c include metals such as Al, Mo, Co, Zr, Sn, Nb, Fe, Cr, Ta, Ti, Au, Pt, V, Mn, Ni, Cu, Hf, W, Ir, Zn, In, Pd, Nd, and Ag, alloys of these metals, conductive films made of metal oxides such as tin oxide, zinc oxide, rhenium oxide, indium oxide, indium tin oxide (ITO), and indium zinc oxide (IZO), organic conductive compounds such as polyaniline, polythiophene, and polypyrrole, and mixtures thereof. A deposition method for the electrode is not particularly limited. The electrode is formable on the substrate by a method appropriately selected in consideration of suitability for the material from a wet method such as printing, spraying, or coating, a physical method such as vacuum evaporation, sputtering, or ion plating, and a chemical method such as CVD or plasma CVD, for example.

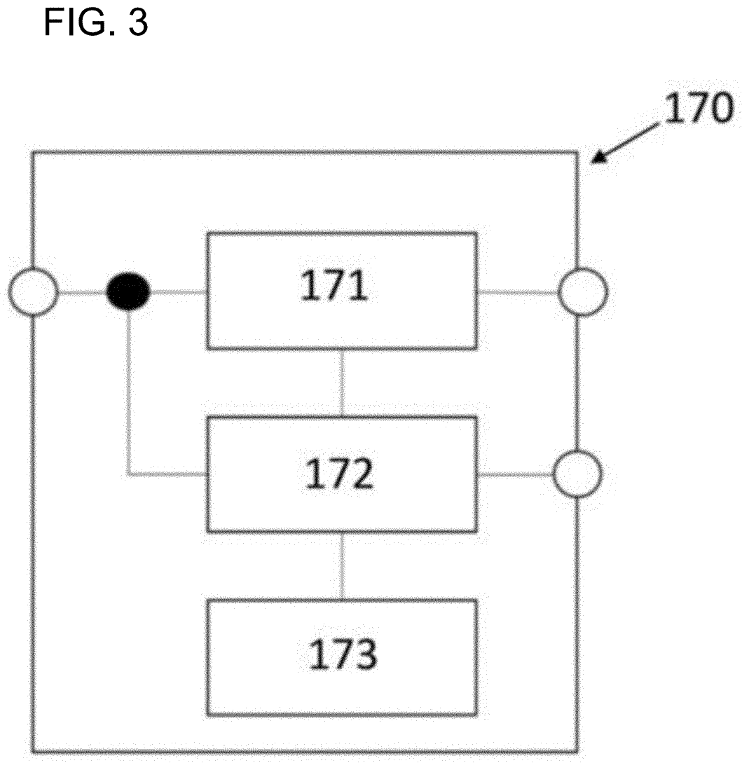

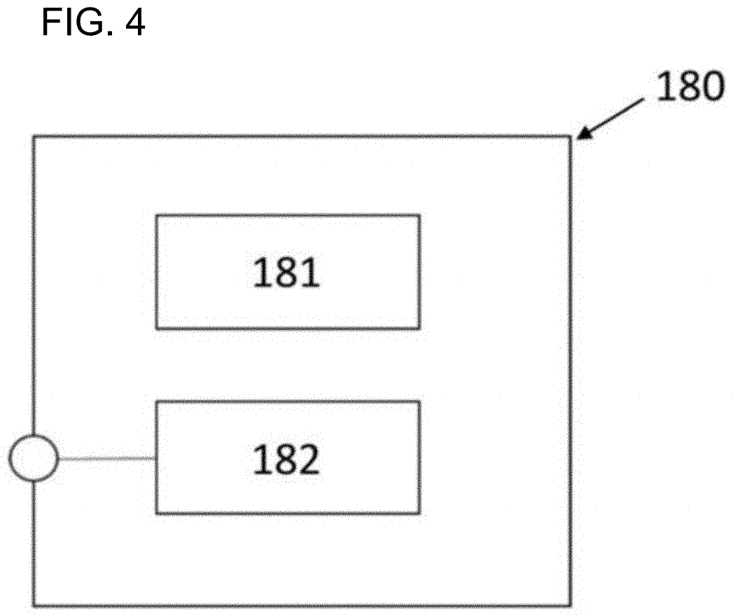

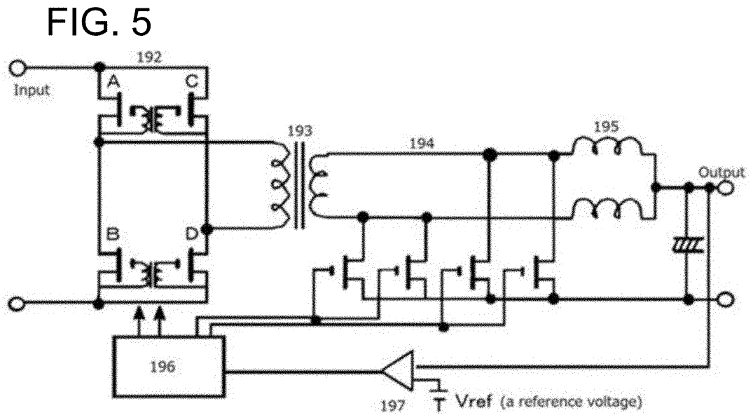

In addition to the matters described above, the semiconductor device according to the disclosure may preferably be used as a power module, an inverter, or a converter using a publicly-known method, and is also preferably used in a semiconductor system including a power source device, for example. The power source device may be provided from the semiconductor device or may be provided as the semiconductor device by being connected to a wiring pattern, for example, using a common method. In FIG. 3, a power source system 170 is configured using a plurality of such power source devices 171 and 172 and a control circuit 173. As illustrated in FIG. 4, the power source system is usable in a system device 180 including an electronic circuit 181 and a power source system 182 in combination. FIG. 5 illustrates an example of a power source circuit diagram of the power source device. FIG. 5 illustrates a power source circuit of a power source device including a power circuit and a control circuit. A DC voltage is switched and converted to AC at a high frequency by an inverter 192 (composed of MOSFETs A to D), and is then subjected to insulation and transformation by a transformer 193. The voltage is then rectified by rectification MOSFETs 194 (A to B′) and then smoothed by a DCL 195 (smoothing coils L1 and L2) and a capacitor to output a direct current voltage. At this point, the output voltage is compared with a reference voltage by a voltage comparator 197 to control the inverter 192 and the rectification MOSFETs 194 using a PWM control circuit 196, thereby obtaining a desired output voltage.

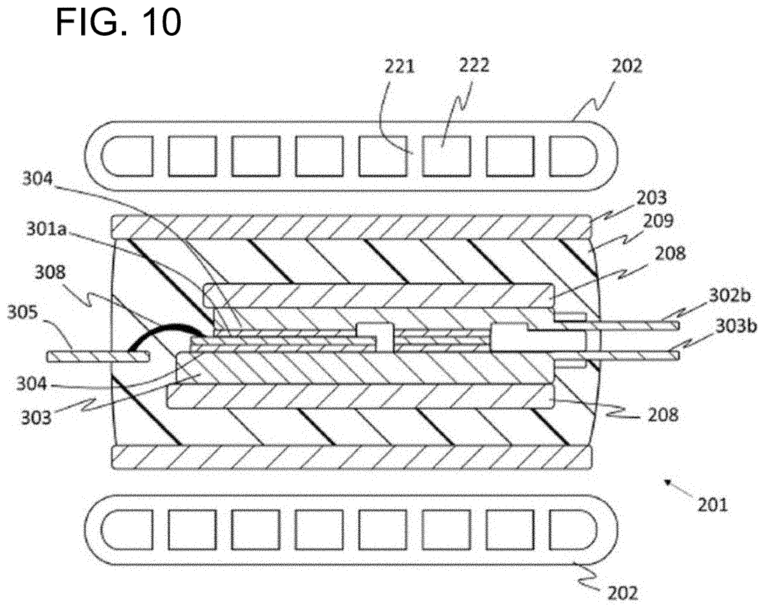

According to the disclosure, the semiconductor device is preferably a power card. More preferably, the power card includes a cooler and an insulating member and the cooler is provided on each of both sides of the semiconductor layer across at least the insulating member. Most preferably, a heat dissipation layer is provided on each of the both sides of the semiconductor layer and the cooler is provided external to the heat dissipation layer across at least the insulating member. FIG. 10 illustrates a power card according to one preferred embodiment of the disclosure. The power card in FIG. 10 is a double-sided cooling power card 201 including a coolant tube 202, a spacer 203, an insulating plate (insulating spacer) 208, a resin sealing part 209, a semiconductor chip 301a, a metal heat transfer plate (projecting terminal part) 302b, a heat sink and electrode 303, a metal heat transfer plate (projecting terminal part) 303b, a solder layer 304, a control electrode terminal 305, and a bonding wire 308. The coolant tube 202 has a section in a thickness direction provided with a large number of flow paths 222 separated with a large number of partitions 221 arranged at intervals therebetween and extending in a flow path direction. This preferred power card achieves higher heat dissipation performance and fulfills higher reliability.

The semiconductor chip 301a is joined to an inner principal plane of the metal heat transfer plate 302b with the solder layer 304. The metal heat transfer plate (projecting terminal part) 302b is joined to the residual principal plane of the semiconductor chip 301a with the solder layer 304. By doing so, an anode electrode surface and a cathode electrode surface of a flywheel diode are connected in so-called inverse-parallel to a collector electrode surface and an emitter electrode surface of an IGBT. The metal heat transfer plates (projecting terminal parts) 302b and 303b are made of a material that is Mo or W, for example. The metal heat transfer plates (projecting terminal parts) 302b and 303b have a difference in thickness with which a difference in thickness of semiconductor chips 301a is absorbed to define an outer surface of the metal heat transfer plate 302b and 303b as a flat surface.

The resin sealing part 209 is made of epoxy resin, for example, and is molded while covering side surfaces of the metal heat transfer plates 302b and 303b. The semiconductor chip 301a is molded with the resin sealing part 209. Outer principal planes, namely, heat-receiving contact surfaces of the metal heat transfer plates 302b and 303b are completely exposed. The metal heat transfer plates (projecting terminal parts) 302b and 303b project rightward from the resin sealing part 209 in FIG. 10. The control electrode terminal 305 that is a so-called lead frame terminal forms connection between a gate (control) electrode surface and the control electrode terminal 305 of the semiconductor chip 301a where an IGBT is formed, for example.

While the insulating plate 208 as an insulating spacer is composed of an aluminum nitride film, for example, it may be a different insulating film. The insulating plate 208 tightly contacts the metal heat transfer plates 302b and 303b while covering the metal heat transfer plates 302b and 303b completely. Alternatively, the insulating plate 208 may simply contact the metal heat transfer plates 302b and 303b, or a member to transfer heat favorably such as silicone grease may be applied. Various methods are applicable to form a joint therebetween. An insulating layer may be formed by ceramic spraying, for example. The insulating plate 208 may be joined onto the metal heat transfer plate or may be joined onto or formed on the coolant tube.

The coolant tube 202 is prepared by cutting a plate material formed by pultrusion molding or extrusion molding on an aluminum alloy into a required length. The section in a thickness direction of the coolant tube 202 includes the large number of flow paths 222 separated with the large number of partitions 221 arranged at intervals therebetween and extending in the flow path direction. The spacer 203 may be a soft metal plate such as a solder alloy, for example. The spacer 203 may also be a film (coating) formed on the contact surfaces of the metal heat transfer plates 302b and 303b by coating, for example. The soft spacer 203 has a surface that is easy to deform and is adaptable to fine irregularities or distortion of the insulating plate 208 and to fine irregularities or distortion of the coolant tube 202, thereby reducing thermal resistance. A publicly-known member to transfer heat favorably such as grease may be applied, for example to a surface of the spacer 203. The spacer 203 is omissible.

### Test Examples 1 to 3

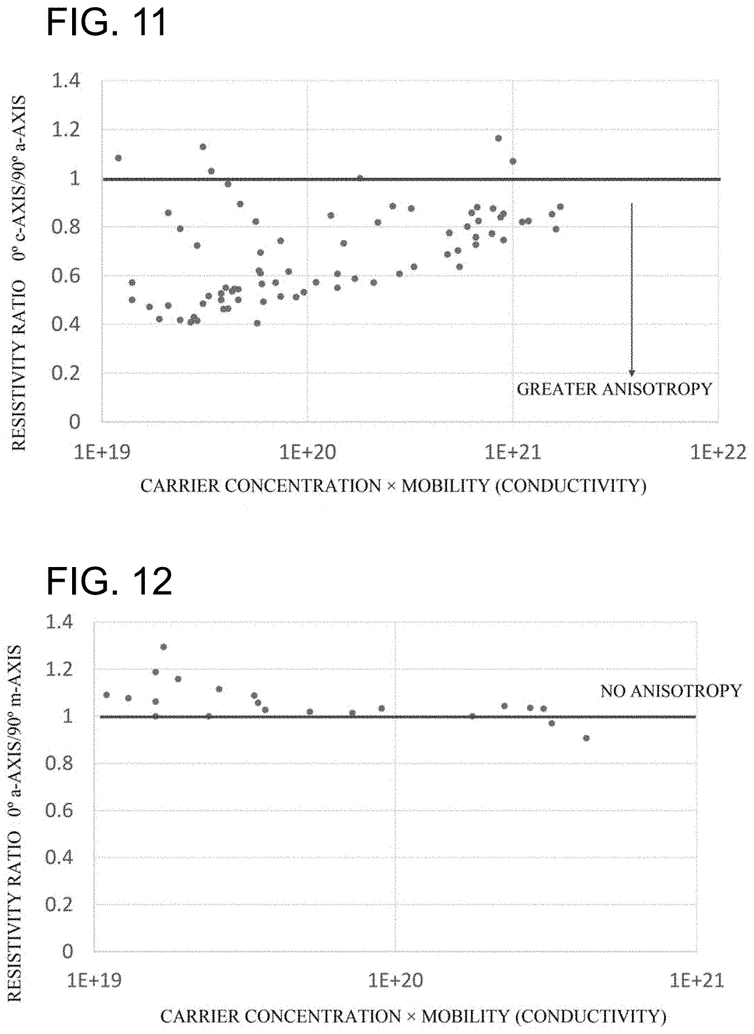

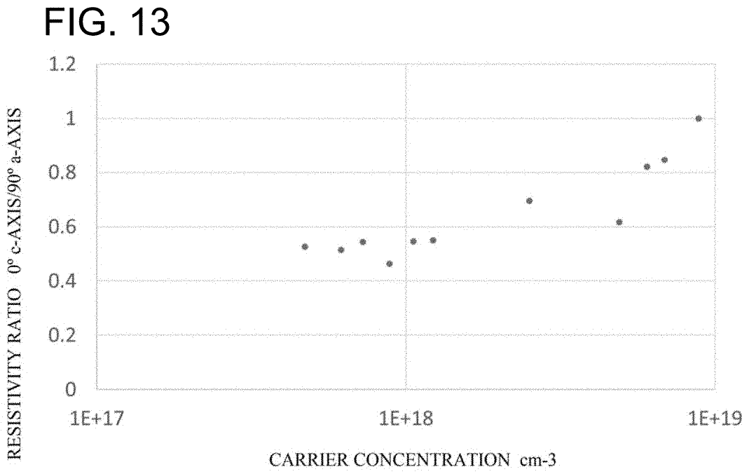

An m-plane α-Ga₂O₃ semiconductor film and a c-plane α-Ga₂O₃ semiconductor film were deposited using a mist CVD method. Then, using a terahertz spectral device (general-purpose terahertz spectral device “TerapProspector (registered trademark, trademark registration No. 5550188)” (2019) available from NIPPO PRECISION Co. Ltd.), a relationship between an electrical resistivity and carrier concentration×mobility (conductivity) was analyzed to evaluate anisotropy between a c-axis and an a-axis. Results thereof are illustrated in FIG. 11 (test example 1) and FIG. 12 (test example 2). As clearly understood from FIGS. 11 and 12, anisotropy by which the resistivity becomes lower in the c-axis direction was observed. Anisotropy by which the resistivity slightly becomes lower along an m-axis was also observed. Furthermore, a carrier concentration about each sample in the test example 1 was examined using a Hall effect measuring device and results illustrated in FIG. 13 (test example 3) were obtained. These results show that a lower carrier concentration results in greater anisotropy.

The semiconductor device according to the disclosure is available in any field including semiconductors (e.g., compound semiconductor electronic devices), electronic parts, electric equipment parts, optical electrophotographic related apparatuses, industrial members, and especially useful for power devices.

The embodiments of the present invention are exemplified in all respects, and the scope of the present invention includes all modifications within the meaning and scope equivalent to the scope of claims.

### REFERENCE SIGNS LIST

1a First semiconductor region
1b Second semiconductor region
2 Oxide semiconductor film
2a Inversion channel region
2b Oxide film
4a Insulating film
4b Insulating film
5a Third electrode
5b First electrode
5c Second electrode
9 Substrate
19 Deposition apparatus
20 Substrate
21 Susceptor
22a Carrier gas source
22b Carrier gas (diluted) source
23a Flow control valve for carrier gas
23b Flow control valve for carrier gas (diluted)
24 Mist generator
24a Raw material solution
24b Atomized droplet
25 Container
25a Water
26 Ultrasonic transducer
27 Supply pipe
28 Hot plate (heater)
29 Exhaust port
30 Deposition chamber
100 Semiconductor device
100a First surface
131a n⁻-type semiconductor layer
131b First n⁺-type semiconductor layer
131c Second n⁺-type semiconductor layer
134 Gate insulating film
135a Gate electrode
135b Source electrode
135c Drain electrode
139 Semi-insulator layer
170 Power source system
171 Power source device
172 Power source device
173 Control circuit
180 System device
181 Electronic circuit
182 Power source system
192 Inverter
193 Transformer
194 Rectification MOSFET
195 DCL
196 PWM control circuit
197 Voltage comparator
200 Semiconductor device
200a First surface
200b Second surface
201 Double-sided cooling power card
202 Coolant tube
203 Spacer
208 Insulating plate (insulating spacer)
209 Resin sealing part
221 Partition
222 Flow path
301a Semiconductor chip
302b Metal heat transfer plate (projecting terminal part)
303 Heat sink and electrode
303b Metal heat transfer plate (projecting terminal part)
304 Solder layer
305 Control electrode terminal
308 Bonding wire

What is claimed is:

1. A semiconductor device comprising;
at least a semiconductor layer; and
a gate electrode that is arranged directly or via another layer on the semiconductor layer,
the semiconductor device being configured in such a manner as to cause a current to flow in the semiconductor layer at least in a first direction that is along with an interface between the semiconductor layer and the gate electrode,
the semiconductor layer having a corundum structure,
a direction of a c-axis in the semiconductor layer being the first direction.

2. The semiconductor device according to claim 1, wherein
the first direction is a direction along with an upper surface of the semiconductor layer.

3. The semiconductor device according to claim 1, wherein
the semiconductor layer contains a metal oxide including at least one metal selected from gallium, indium, rhodium, and iridium.

4. The semiconductor device according to claim 1, wherein
the semiconductor layer contains a metal oxide including at least gallium as a major component.

5. The semiconductor device according to claim 1, wherein
the semiconductor layer has a carrier concentration of equal to or less than 1×10¹⁹/cm³.

6. The semiconductor device according to claim 1, wherein
the first surface is an m-plane.

7. The semiconductor device according to claim 1, wherein
the semiconductor device is a power device.

8. The semiconductor device according to claim 7, wherein
the semiconductor device is a power module, an inverter, or a converter.

9. The semiconductor device according to claim 7, wherein
the semiconductor device is a power card.

10. The semiconductor device according to claim 9, further comprising:
a cooler and an insulating member,
the cooler being provided on each of both sides of the semiconductor layer across at least the insulating member.

11. The semiconductor device according to claim 10, wherein
a heat dissipation layer is provided on each of the both sides of the semiconductor layer, and
the cooler is provided external to the heat dissipation layer across at least the insulating member.

12. A semiconductor system comprising a semiconductor device,
the semiconductor device being the semiconductor device according to claim 1.
